(19) United States
(12) Patent Application Publication
(10) Pub. No.: US 2026/0005016 A1
(43) Pub. Date: Jan. 1, 2026

(54) MANUFACTURING METHOD OF SEMICONDUCTOR STRUCTURE

(71) Applicant: NANYA TECHNOLOGY CORPORATION, New Taipei City (TW)

(72) Inventor: Ying-Cheng CHUANG, New Taipei City (TW)

(21) Appl. No.: 18/760,047

(22) Filed: Jul. 1, 2024

(51) Int. Cl. H01L 21/02; H01L 21/308; H01L 21/324; H01L 21/3105

(52) U.S. Cl. CPC H01L 21/0228; H01L 21/308; H01L 21/324; H01L 21/02123; H01L 21/02554; H01L 21/31051

(57) ABSTRACT

A manufacturing method of a semiconductor structure is provided. The method includes following steps. A substrate is provided. A trench is formed in the substrate, wherein an active area is protruded from the substrate and the active has a first width. A thin silicon layer is formed on the active area and a sidewall of the trench. A first oxide layer is formed on the thin silicon layer by providing oxygen airflow, wherein the first oxide layer is formed in a range of 400°C to 600°C. A second oxide layer is formed to fill the trench and cover the active area, wherein the second oxide layer is formed at a temperature higher than the first oxide layer. And an anneal process is performed to crystalize the thin silicon layer.

### BACKGROUND

### FIELD OF INVENTION

The present disclosure relates to a manufacturing method of a semiconductor structure.

### DESCRIPTION OF RELATED ART

In a semiconductor device, an isolation structure is formed between active areas (AA) for electrically insulated the active areas. As semiconductor devices become smaller and highly integrated, the pitch of the active areas continue to shrink. Accordingly, the size of the isolation structure continues to shrink as well.

However, shrinkage of the pitch of the active areas and shrinkage of the size of the isolation structure may cause short issue.

### SUMMARY

In accordance with an aspect of the present disclosure, a manufacturing method of a semiconductor structure is provided. The method includes following steps. A substrate is provided. A trench is formed in the substrate, wherein an active area is protruded from the substrate and the active area has a first width. A thin silicon layer is formed on the active area and a sidewall of the trench. A first oxide layer is formed on the thin silicon layer by providing oxygen airflow, wherein the first oxide layer is formed in a range of 400°C to 600°C. A second oxide layer is formed to fill the trench and cover the active area, wherein the second oxide layer is formed at a temperature higher than the first oxide layer. And an anneal process is performed to crystalize the thin silicon layer.

According to some embodiments of the present disclosure, wherein subsequent to forming the second oxide layer further includes performing a planarization process to the second oxide layer.

According to some embodiments of the present disclosure, wherein subsequent to performing a planarization process a top surface of the second oxide layer and a top surface of the first oxide layer are at same level.

According to some embodiments of the present disclosure, wherein subsequent to performing a planarization process a top surface of the second oxide layer and a top surface of the active area are at same level.

According to some embodiments of the present disclosure, wherein subsequent to performing the anneal process the active area has a second width that is larger than the first width.

According to some embodiments of the present disclosure, wherein the formation of the second oxide layer comprises a first stage and a second stage.

According to some embodiments of the present disclosure, wherein the first stage comprises introducing oxygen and hydrogen in a ratio of 4.

According to some embodiments of the present disclosure, wherein the second stage is a cyclic process includes following steps. An HCDS (Hexachlorodisilane) flow is introduced. A first vacuum purging process and introducing a first inert gas is performed. Oxygen and hydrogen in a ratio of 4 are introduced. And a second vacuum purging process is performed and a second inert gas is introduced.

In accordance with an aspect of the present disclosure, a manufacturing method of a semiconductor structure is provided. The method includes following steps. A substrate is provided. A hard mask layer is formed on the substrate. A portion of the hard mask layer is removed to form a hard mask. A trench is formed in the substrate according to the hard mask, wherein an active area is protruded from the substrate and the active area has a first width. A thin silicon layer is formed on the active area and a sidewall of the trench. A first oxide layer is formed on the thin silicon layer by introducing oxygen and hydrogen in a first ratio, wherein the first oxide layer is formed in a range of 400°C to 600°C. A second oxide layer is formed to fill the trench and cover the active area, wherein the second oxide layer is formed at a temperature higher than the first oxide layer. And an anneal process is performed to crystalize the thin silicon layer.

According to some embodiments of the present disclosure, wherein prior to forming the thin silicon layer further includes removing the hard mask to expose a top surface of the active area.

According to some embodiments of the present disclosure, wherein subsequent to performing the anneal process the active area has a second width that is larger than the first width.

According to some embodiments of the present disclosure, wherein the formation of the second oxide layer comprises a first stage and a second stage.

According to some embodiments of the present disclosure, wherein the first stage comprises introducing oxygen and hydrogen in a second ratio, wherein the second ratio is smaller than the first ratio.

According to some embodiments of the present disclosure, wherein the first stage is performed in 600°C for 30 seconds.

According to some embodiments of the present disclosure, wherein the second stage is a cyclic process includes following steps. An HCDS (Hexachlorodisilane) flow is introduced. A first vacuum purging process and introducing a first inert gas is performed. Oxygen and hydrogen in the second ratio are introduced. And a second vacuum purging process is performed and a second inert gas is introduced.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view schematic diagram of a semiconductor structure, in accordance with some embodiments;

FIG. 2 is a cross-sectional view schematic diagram of a semiconductor structure after forming a hard mask, in accordance with some embodiments;

FIG. 3 is a cross-sectional view schematic diagram of a semiconductor device after forming a trench, in accordance with some embodiments;

FIG. 4 is a cross-sectional view schematic diagram of a semiconductor device after removing the hard mask, in accordance with some embodiments;

FIG. 5 is a cross-sectional view schematic diagram of a semiconductor device after forming a thing silicon layer, in accordance with some embodiments;

FIG. 6 is a cross-sectional view schematic diagram of a semiconductor device after forming a first oxide layer, in accordance with some embodiments;

FIG. 7 is a cross-sectional view schematic diagram of a semiconductor device after forming a second oxide layer, in accordance with some embodiments;

FIG. 8 is a cross-sectional view schematic diagram of a semiconductor device after performing an anneal process, in accordance with some embodiments; and

FIG. 9 is a flow chart of a semiconductor device of forming the first oxide layer and the second oxide layer, in accordance with some embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

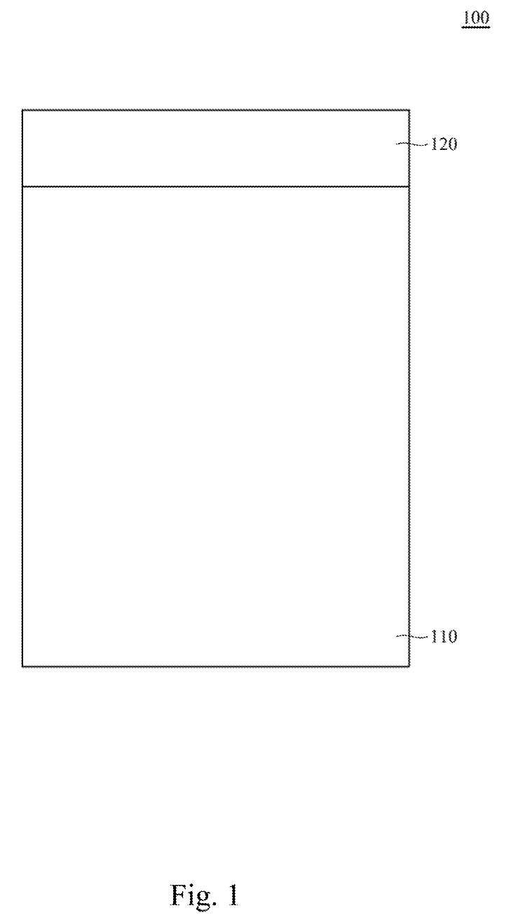

FIG. 1 to FIG. 8 are cross-sectional views of a manufacturing method of a semiconductor structure 100 in various stages in accordance with some embodiments of the present disclosure. It is noted that the semiconductor structure 100 includes an array area and a periphery area adjacent to the array area. For clarify, the present disclosure illustrates the array area of the semiconductor structure in FIG. 1 to FIG. 8, and the periphery area of the semiconductor structure is not shown in FIG. 1 to FIG. 8.

Referring to FIG. 1, a substrate 110 is provided. The substrate 110 may include an elementary semiconductor, such as germanium, or silicon; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In addition, the substrate 110 may be a p-type substrate, such as a silicon material doped with a p-type dopant (e.g., boron).

In some embodiments, a hard mask layer 120 is formed on the substrate 110. In some embodiments, the hard mask layer 120 may include silicon nitride, silicon oxide, silicon oxynitride, silicon carbide, or the like. The hard mask layer 120 can be formed by any suitable deposition method, such as plasma-enhanced atomic layer deposition (PEALD), chemical vapor deposition (CVD), plasma-enhanced chemical vapor deposition (PECVD), physical vapor deposition (PVD), and the like. In some embodiments, the hard mask layer 120 may include one or more layers. If the hard mask layer 120 includes more than one layer, the layers may be made of different materials.

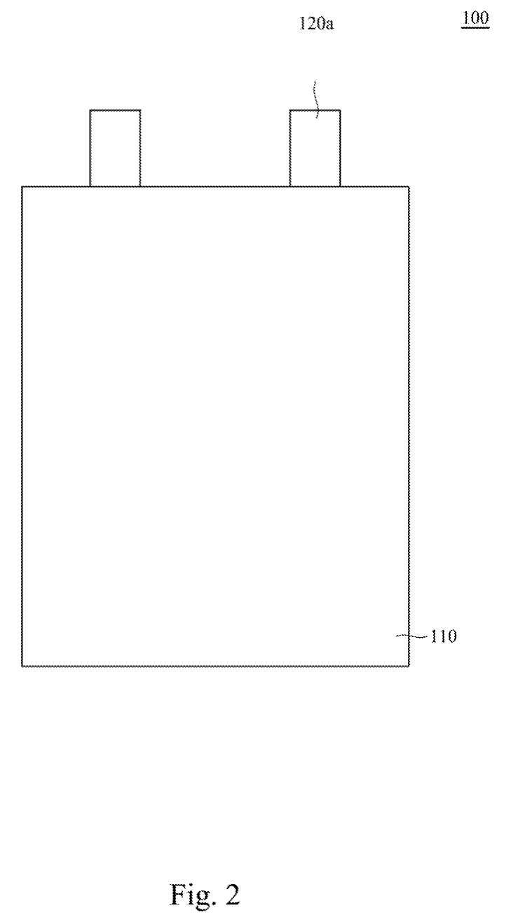

Referring to FIG. 2, a portion of the hard mask layer 120 is removed to form a hard mask 120a. After the hard mask 120a is formed, a portion of the top surface of the substrate 110 is exposed. The portion of the substrate covered by the hard mask 120a can be formed as the active area in the array area in subsequent processes.

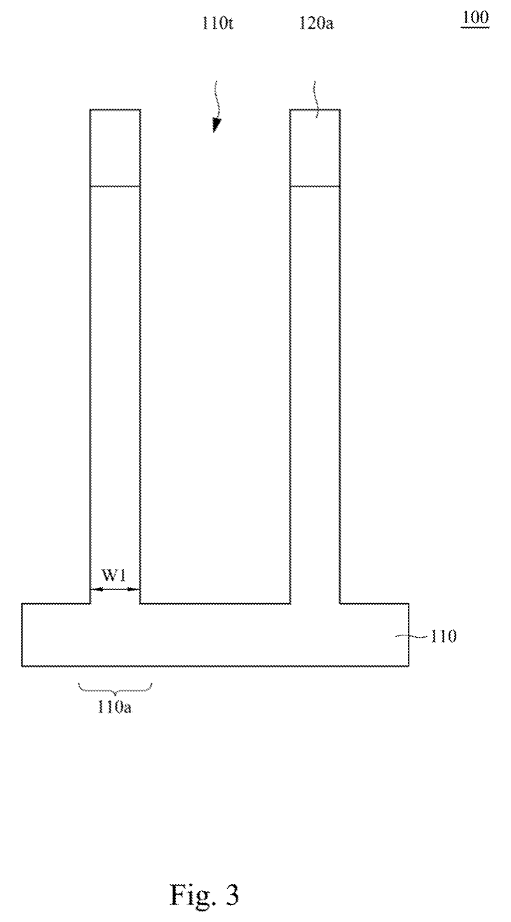

Referring to FIG. 3, the substrate 110 is defined and etched with the hard mask 120a to form a trench 110t and an active area 110a in the substrate 110. The bottom surface 112 of the trench 110t is exposed. The trench 110t is provided between the active areas 110a, that is, the trench 110t shares side walls 114 with the two adjacent active areas 110a. In other words, the substrate 110 is etched to define a plurality of island-shaped active areas 110a, and the trench 110t is formed between the active areas 110a. In some embodiments, the substrate 110 is etched by performing a dry etching process, such as a reactive ion etching (RIE) process. In some embodiments, an active area 110a has a width W1 between its two side walls 114.

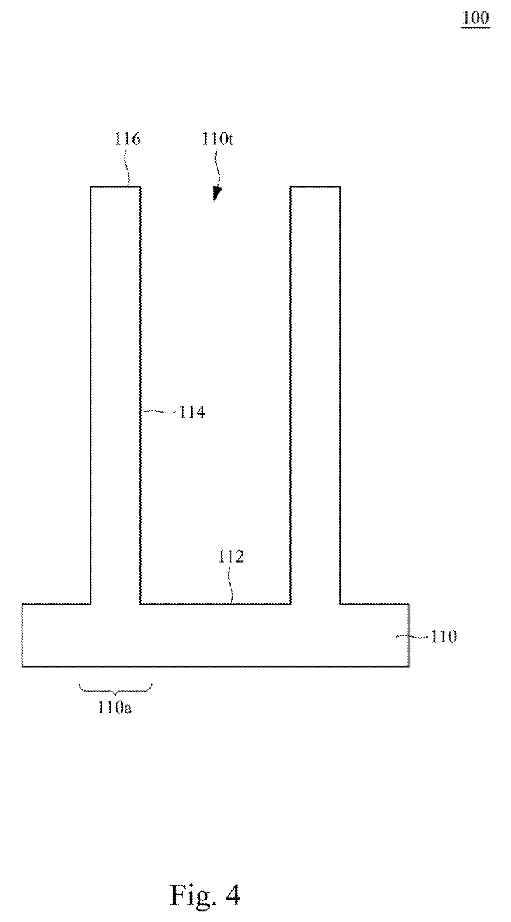

Referring to FIG. 4, the hard mask 120a (as shown in FIG. 3) is removed to expose the top surface 116 of the active area 110a. The hard mask 120a may be removed by any suitable etching process, such as dry etching process or wet etching process.

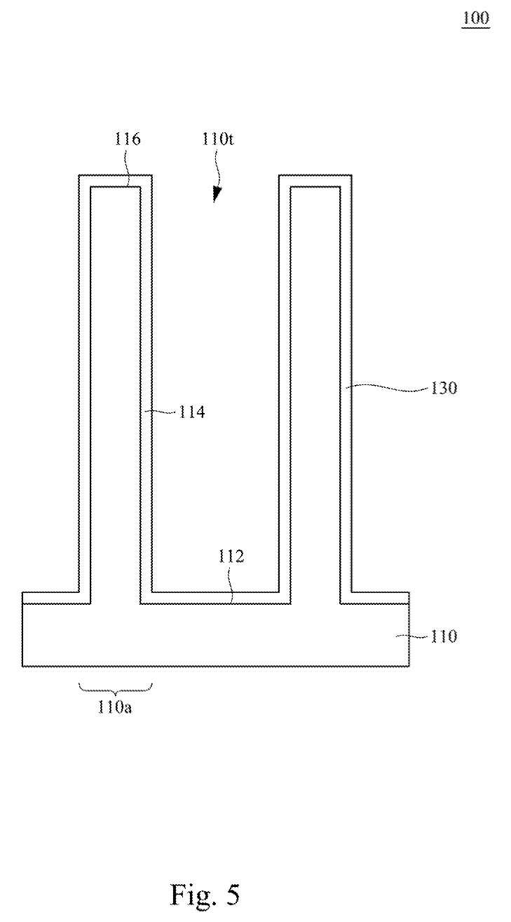

Then referring to FIG. 5, a thin silicon layer 130 is formed on the active area 110a. In detail, the thin silicon layer 130 is formed and covers the bottom surface 112 of the trench 110t, the side wall 114 of the active area 110a, and the top surface 116 of the active area 110a. The thin silicon layer 130 can be formed by any suitable deposition method, such as plasma-enhanced atomic layer deposition (PEALD), chemical vapor deposition (CVD), plasma-enhanced chemical vapor deposition (PECVD), physical vapor deposition (PVD), and the like. In some embodiments, the thin silicon layer 130 includes amorphous silicon. The thin silicon layer 130 is formed to enlarge the active area 110a.

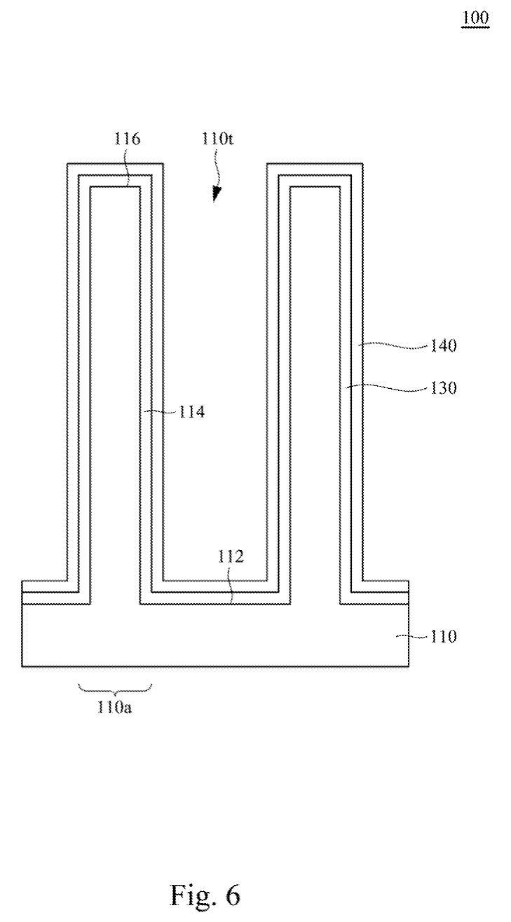

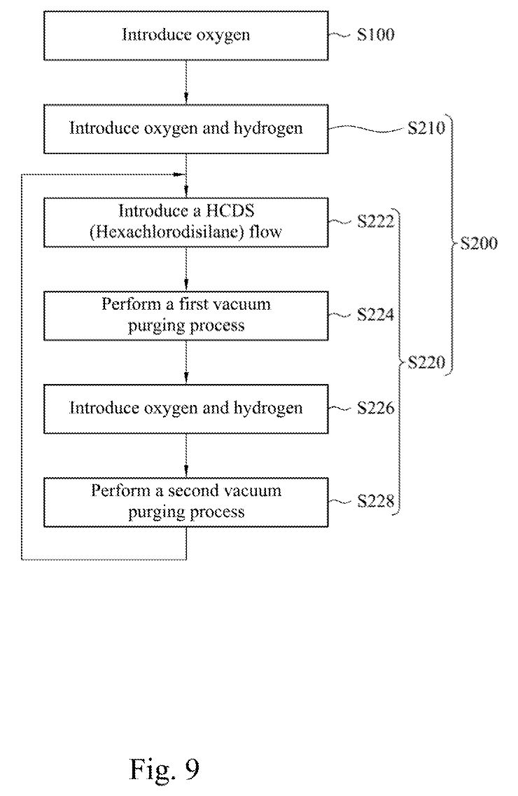

Next referring to FIG. 6 and FIG. 9, in step S100, a first oxide layer 140 is formed on the thin silicon layer 130. Similarly, the first oxide 140 is formed and covers the bottom surface 112 of the trench 110t, the side wall 114 of the active area 110a, and the top surface 116 of the active area 110a. In some embodiments, the precursor of forming the first oxide layer 140 includes oxygen (O₂) airflow. In other embodiments, the precursor of forming the first oxide layer 140 includes oxygen (O₂) and hydrogen (H₂) in a first ratio. For example, the first ratio can be larger than 4. The first oxide layer 140 is formed in a range of 400°C to 600°C.

As the thin silicon layer 130 may be easily affected by subsequent processes and result in the deposition of rough silicon, which may cause the active area 110a to occur short issue. The first oxide layer 140 is formed to prevent deposition of rough silicon in subsequent processes.

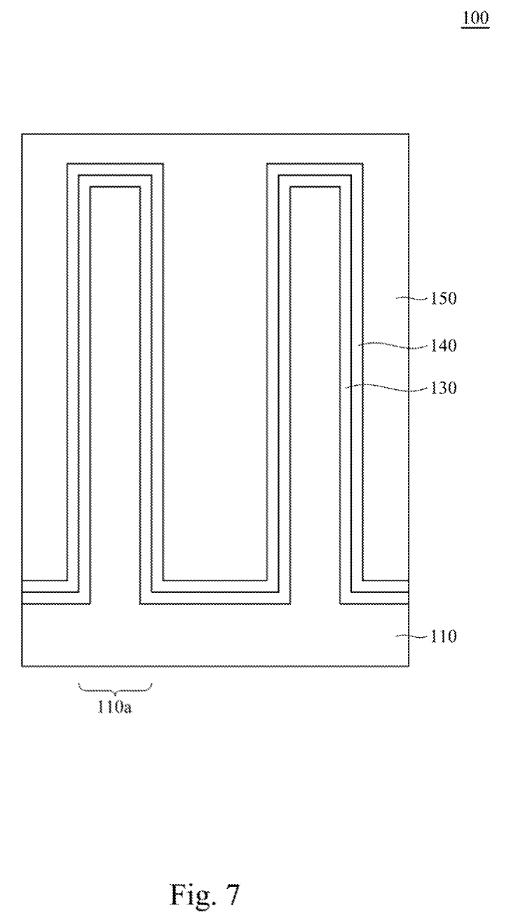

Referring to FIG. 7 and Fig.9, by method S200, a second oxide layer 150 is formed in the trench 110t. In detail, the second oxide layer 150 is formed to fill the trench 110t and over top surface 116 of the active area 110a. In some embodiments, the second oxide layer 150 can be formed by chemical vapor deposition (CVD). For example, the second oxide layer 150 can be formed by flowable chemical vapor deposition (FCVD) process. The second oxide layer 150 can be formed by a first stage S210 and a second stage S220. In the first stage S210, a precursor is introduced, and the precursor includes oxygen and hydrogen in a second ratio, wherein the second ration can be 4. In some embodiments, the first stage is performed for 30 seconds and the temperature is around 600 degrees. Then, the second stage S220 is performed, and the second stage is a cyclic process that includes step S222, step S224, step S226, and step S228. In step S222 of the second stage S220, an HCDS (Hexachlorodisilane) flow is introduced. In step S226 of the second stage S220, a first vacuum purging process is performed and a first inert gas such as nitrogen (N2) is introduced. In step S226 of the second stage S220, the precursor includes oxygen and hydrogen in a second ratio is introduced, wherein the second ratio can be 4. Finally, in step S228 of the second stage S220, a second vacuum purging process is performed and a second inert gas such as nitrogen (N2) is introduced. Then, repeat the second stage S220 for several times until the trench 110t is completely filled by the second oxide layer 150. In some embodiments, the second oxide layer may include silicon oxide. It is noted that the first oxide layer 140 and the second oxide layer can be formed in same reaction chamber.

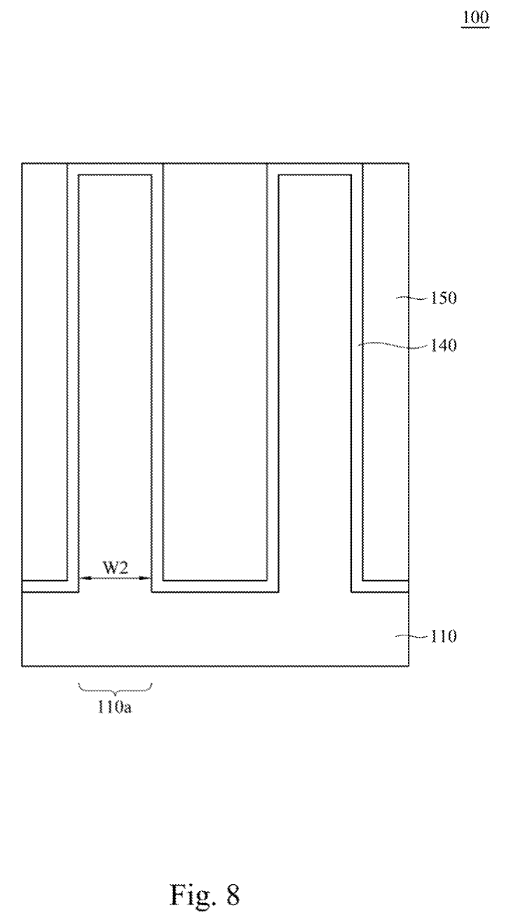

Referring to FIG. 8, an anneal process is performed to crystalize the thin silicon layer 130 and enlarge the active area 110a. After the anneal process, the active area 110a has a width W2, wherein the width W2 is larger than width W1 (shown in FIG. 3). In some embodiments, a planarization process may be performed to remove a portion of the second oxide layer 150. For example, the planarization process may include chemical mechanical planarization (CMP) process. In some embodiments, after the planarization process is performed, a top surface of the first oxide layer 140 is exposed. In other embodiments, after the planarization process is performed, the top surface 116 of the active area 110a is exposed.

The present disclosure provides a manufacturing method of a semiconductor structure. The method of the present disclosure includes forming a first oxide layer by introducing oxygen airflow after forming thin silicon layer. The method of the present disclosure may increase the size of the active area (or decrease the pitch between active areas) while reducing the short circuit caused by the deposition of rough silicon between the active area in a simple and concise process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a semiconductor structure, comprising:
providing a substrate;
forming a trench in the substrate, wherein an active area is protruded from the substrate and the active area has a first width;
forming a thin silicon layer on the active area and a sidewall of the trench;
forming a first oxide layer on the thin silicon layer by providing oxygen airflow, wherein the first oxide layer is formed in a range of 400°C to 600°C;
forming a second oxide layer to fill the trench and cover the active area, wherein the second oxide layer is formed at a temperature higher than the first oxide layer; and
performing an anneal process to crystalize the thin silicon layer.

2. The manufacturing method of a semiconductor structure of claim 1, wherein subsequent to forming the second oxide layer further comprises:
performing a planarization process to the second oxide layer.

3. The manufacturing method of a semiconductor structure of claim 2, wherein subsequent to performing a planarization process a top surface of the second oxide layer and a top surface of the first oxide layer are at same level.

4. The manufacturing method of a semiconductor structure of claim 2, wherein subsequent to performing a planarization process a top surface of the second oxide layer and a top surface of the active area are at same level.

5. The manufacturing method of a semiconductor structure of claim 1, wherein subsequent to performing the anneal process the active area has a second width that is larger than the first width.

6. The manufacturing method of a semiconductor structure of claim 1, wherein the formation of the second oxide layer comprises a first stage and a second stage.

7. The manufacturing method of a semiconductor structure of claim 6, wherein the first stage comprises introducing oxygen and hydrogen in a ratio of 4.

8. The manufacturing method of a semiconductor structure of claim 7, wherein the second stage is a cyclic process comprises:
introducing an HCDS (Hexachlorodisilane) flow;
performing a first vacuum purging process and introducing a first inert gas;
introducing oxygen and hydrogen in a ratio of 4; and
performing a second vacuum purging process and introducing a second inert gas.

9. A manufacturing method of a semiconductor structure, comprising:
providing a substrate;
forming a hard mask layer on the substrate;
removing a portion of the hard mask layer to form a hard mask;
forming a trench in the substrate according to the hard mask, wherein an active area is protruded from the substrate and the active area has a first width;
forming a thin silicon layer on the active area and a sidewall of the trench;
forming a first oxide layer on the thin silicon layer by introducing oxygen and hydrogen in a first ratio, wherein the first oxide layer is formed in a range of 400°C to 600°C;
forming a second oxide layer to fill the trench and cover the active area, wherein the second oxide layer is formed at a temperature higher than the first oxide layer; and
performing an anneal process to crystalize the thin silicon layer.

10. The manufacturing method of a semiconductor structure of claim 9, wherein prior to forming the thin silicon layer further comprises:
removing the hard mask to expose a top surface of the active area.

11. The manufacturing method of a semiconductor structure of claim 9, wherein subsequent to performing the anneal process the active area has a second width that is larger than the first width.

12. The manufacturing method of a semiconductor structure of claim 9, wherein the formation of the second oxide layer comprises a first stage and a second stage.

13. The manufacturing method of a semiconductor structure of claim 12, wherein the first stage comprises introducing oxygen and hydrogen in a second ratio, wherein the second ratio is smaller than the first ratio.

14. The manufacturing method of a semiconductor structure of claim 13, wherein the first stage is performed in 600°C for 30 seconds.

15. The manufacturing method of a semiconductor structure of claim 13, wherein the second stage is a cyclic process comprising:
introducing an HCDS (Hexachlorodisilane) flow;
performing a first vacuum purging process and introducing a first inert gas;
introducing oxygen and hydrogen in the second ratio; and
performing a second vacuum purging process and introducing a second inert gas.
